(19) United States
(12) Patent Application Publication
(10) Pub. No.: US 2026/0354254 A1
(43) Pub. Date: Nov. 5, 2026

(54) FAN-OUT SEMICONDUCTOR PACKAGE

(71) Applicant: SK hynix Inc., Icheon-si Gyeonggi-do (KR)

(72) Inventors: Su Jeong CHOI, Icheon-si Gyeonggi-do (KR); Ki Jun SUNG, Icheon-si Gyeonggi-do (KR)

(73) Assignee: SK hynix Inc., Icheon-si Gyeonggi-do (KR)

(21) Appl. No.: 19/358,673

(22) Filed: Oct. 15, 2025

(30) Foreign Application Priority Data
May 2, 2025 (KR) 10-2025-0057943

(51) Int. Cl. H10W 74/10; H10B 80/00; H10W 90/00; H10W 72/00; H10W 90/20; H10W 90/24

(52) U.S. Cl. CPC H10W 74/121; H10B 80/00; H10W 90/00; H10W 90/701; H10W 72/877; H10W 90/20; H10W 90/24; H10W 90/724; H10W 90/732; H10W 90/734

(57) ABSTRACT

A semiconductor package includes a first outer molding layer; a first chip structure including a first semiconductor chip, a first metal pillar, a second semiconductor chip offset-stacked on the first semiconductor chip, a second metal pillar, and a first inner molding layer; a second chip structure including a third semiconductor chip, a third metal pillar, a fourth semiconductor chip offset-stacked on the third semiconductor chip, a fourth metal pillar, and a second inner molding layer; a first bonding pad disposed on the first metal pillar; a second bonding pad disposed on the second metal pillar; a first bonding wire disposed on the first bonding pad; a second bonding wire disposed on the second bonding pad; a second outer molding layer; and a redistribution layer disposed on the second chip structure, the first bonding wire, the second bonding wire, and the second outer molding layer.

### CROSS REFERENCE TO RELATED APPLICATION

The present application claims priority under 35 U.S.C. §119(a) to Korean Patent Application No. 10-2025-0057943 filed in the Korean Intellectual Property Office on May 2, 2025, which application is incorporated herein by reference in its entirety.

### BACKGROUND

### 1. Technical Field

The present disclosure relates to a fan-out semiconductor package.

### 2. Related Art

A semiconductor chip includes an integrated circuit that stores data or processes data. The semiconductor chip includes a chip pad used to input data to the integrated circuit or output data from the integrated circuit to an external device. A semiconductor package electrically connects the semiconductor chip to the external device.

Various methods may be used to electrically connect a chip pad to an external device. A semiconductor package using a redistribution layer has a redistribution pattern that is electrically connected to a chip pad. Among semiconductor packages using a redistribution layer, a fan-out package is a technology that extends a redistribution pattern connected to a chip pad to the outside of a region where a semiconductor chip is disposed and disposes an external connection terminal on the redistribution pattern. The fan-out package has advantages that the number and pitch of external connection terminals are not limited by the size of a chip and a standardized ball layout may be used regardless of the size of a chip.

### SUMMARY

In an embodiment, a semiconductor package may include: a first outer molding layer; a first chip structure disposed on the first outer molding layer, and including a first semiconductor chip, a first metal pillar disposed on the first semiconductor chip, a second semiconductor chip offset-stacked on the first semiconductor chip, a second metal pillar disposed on the second semiconductor chip, and a first inner molding layer covering the first semiconductor chip and the second semiconductor chip and surrounding the first metal pillar and the second metal pillar; a second chip structure disposed on the first chip structure, and including a third semiconductor chip, a third metal pillar disposed on the third semiconductor chip, a fourth semiconductor chip offset-stacked on the third semiconductor chip, a fourth metal pillar disposed on the fourth semiconductor chip, and a second inner molding layer covering the third semiconductor chip and the fourth semiconductor chip and surrounding the third metal pillar and the fourth metal pillar; a first bonding pad disposed on the first metal pillar; a second bonding pad disposed on the second metal pillar; a first bonding wire disposed on the first bonding pad; a second bonding wire disposed on the second bonding pad; a second outer molding layer covering the first chip structure and the first bonding pad and the second bonding pad, and surrounding the second chip structure and the first bonding wire and the second bonding wire; and a redistribution layer disposed on the second chip structure, the first bonding wire, the second bonding wire, and the second outer molding layer.

In an embodiment, a semiconductor package may include: a first outer molding layer; a first semiconductor chip disposed on the first outer molding layer; a first metal pillar disposed on the first semiconductor chip; a second semiconductor chip offset-stacked on the first semiconductor chip; a second metal pillar disposed on the second semiconductor chip; a first inner molding layer covering the first semiconductor chip and the second semiconductor chip and surrounding the first metal pillar and the second metal pillar; a third semiconductor chip disposed on the first inner molding layer; a third metal pillar disposed on the third semiconductor chip; a fourth semiconductor chip offset-stacked on the third semiconductor chip; a fourth metal pillar disposed on the fourth semiconductor chip; a second inner molding layer covering the third semiconductor chip and the fourth semiconductor chip and surrounding the third metal pillar and the fourth metal pillar; a first bonding pad disposed on the first metal pillar; a second bonding pad disposed on the second metal pillar; a first bonding wire disposed on the first bonding pad; a second bonding wire disposed on the second bonding pad; a second outer molding layer covering the first inner molding layer, the first bonding pad, the second bonding pad and surrounding the second inner molding layer, the first bonding wire, and the second bonding wire; and a redistribution layer disposed on the first bonding wire, the second bonding wire, the third metal pillar, the fourth metal pillar, the second inner molding layer, and the second outer molding layer.

### BRIEF DESCRIPTION OF THE DRAWINGS

FIG. 1 is a cross-sectional view of a semiconductor package according to an embodiment of the present disclosure.

FIG. 2 is an enlarged view of a section A of FIG. 1.

FIG. 3 and FIG. 4 each illustrate an embodiment of a first bonding pad according to the present disclosure.

FIG. 5 is an enlarged view of a section B of FIG. 1.

FIG. 6 is an enlarged view of a section C of FIG. 1.

FIG. 7 is a plan view of a first semiconductor chip according to an embodiment of the present disclosure.

FIG. 8 is a plan view illustrating first chip pads, first metal pillars, and first bonding wires of a semiconductor package according to the present disclosure.

FIG. 9 - FIG. 15 are cross-sectional views of a semiconductor package utilizing a method of manufacturing a semiconductor package according to an embodiment of the present disclosure.

FIG. 16 is a cross-sectional view illustrating a semiconductor package according to an embodiment of the present disclosure.

FIG. 17 is an enlarged view of a section E of FIG. 16.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” or “under,” another element, the elements may directly contact each other or an intervening element may be disposed between the elements.

Terms such as “vertical,” “top,” “bottom,” “above,” “below,” “under,” “over,” “on,” “side,” “upper,” “lower,” “overlap,” “left,” “right,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

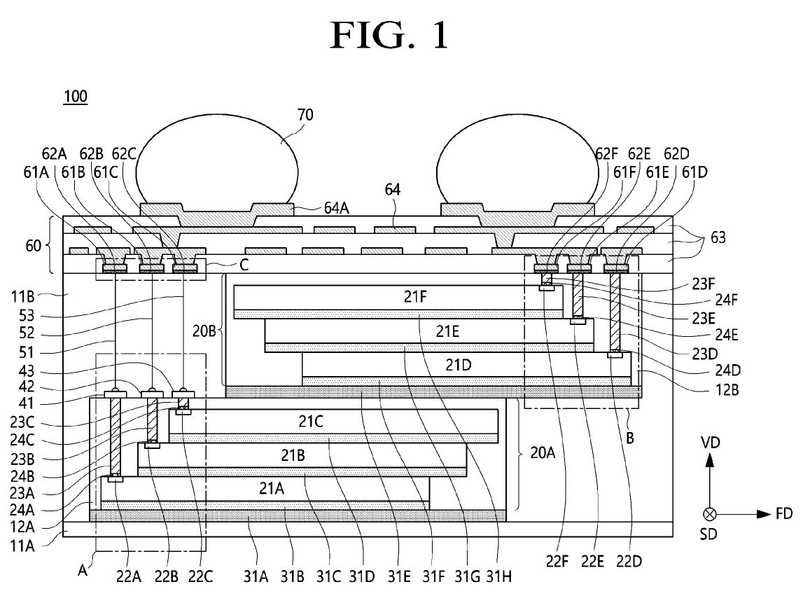

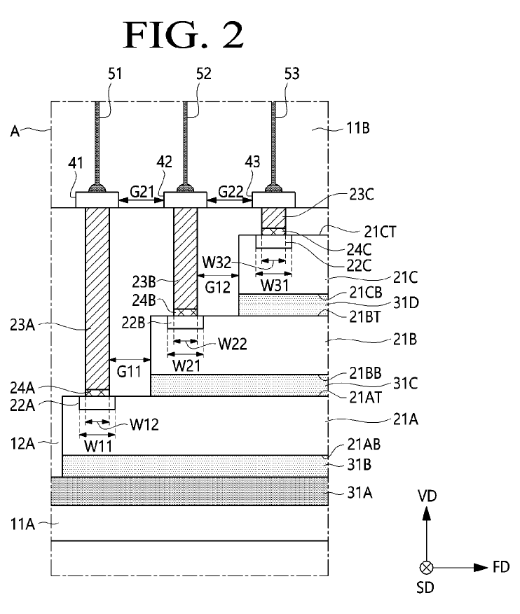

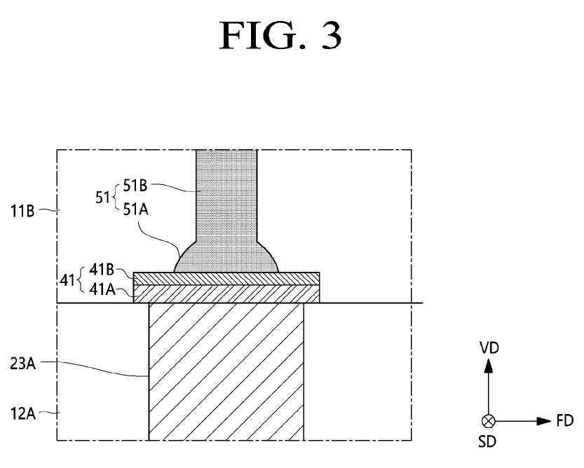

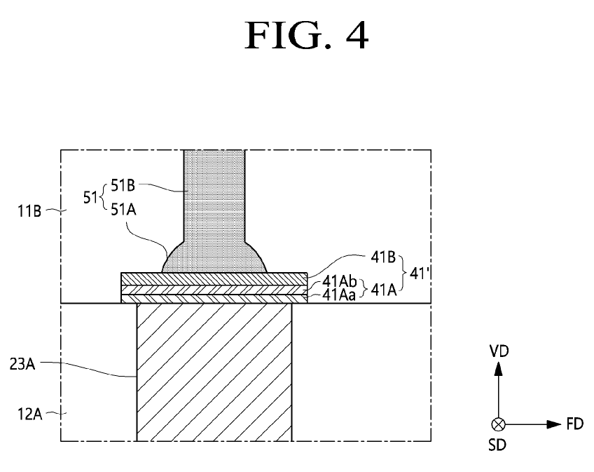

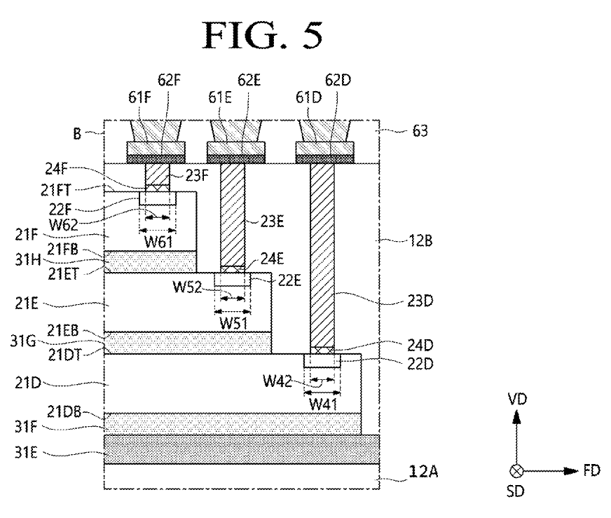

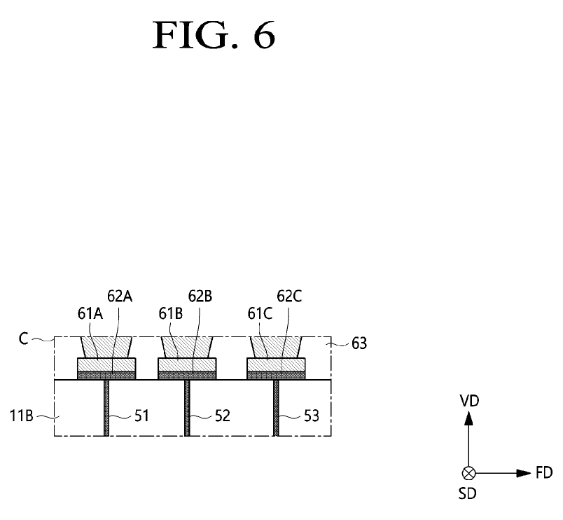

FIG. 1 is a cross-sectional view of a semiconductor package according to an embodiment of the present disclosure, FIG. 2 is an enlarged view of a section A of FIG. 1, FIG. 3 and FIG. 4 are views illustrating examples of a first bonding pad, such as shown in FIG. 1, FIG. 5 is an enlarged view of a section B of FIG. 1, and FIG. 6 is an enlarged view of a section C of FIG. 1.

Referring to FIG. 1, a semiconductor package 100 according to an embodiment of the present disclosure includes a first outer molding layer 11A, a first chip structure or module 20A, a second chip structure or module 20B, a first bonding pad 41, a second bonding pad 42, and a third bonding pad 43, a first bonding wire 51, a second bonding wire 52, and a third bonding wire 53, a second outer molding layer 11B, and a redistribution layer 60. A module simply includes a plurality of components and is not otherwise limiting.

The first outer molding layer 11A includes an insulating layer. The insulating layer may include an epoxy molding compound (EMC). The epoxy molding compound may include resin and filler. The first outer molding layer 11A may include an EMC film that is obtained by processing an EMC into film form.

The first chip module 20A is disposed on the first outer molding layer 11A. The first chip module 20A includes a first semiconductor chip 21A, a second semiconductor chip 21B, a third semiconductor chip 21C, a first metal pillar 23A, a second metal pillars 23B, a third metal pillar 23C, and a first inner molding layer 12A.

The second semiconductor chip 21B is stacked on the first semiconductor chip 21A, and the third semiconductor chip 21C is stacked on the second semiconductor chip 21B. In FIG. 1, the first chip module 20A includes three semiconductor chips, although the present disclosure is not limited to this example. The number of semiconductor chips included in the first chip module 20A may be two or more.

Referring to FIG. 1 and FIG. 2, the first semiconductor chip 21A includes a first integrated circuit (not shown). The first integrated circuit may be implemented in various ways depending on the type of the first semiconductor chip 21A. In an embodiment, the first semiconductor chip 21A is a memory die, and the first integrated circuit includes a memory cell. Memory may include volatile memory or nonvolatile memory. Volatile memory may include dynamic random access memory (DRAM) and static random access memory (SRAM). Nonvolatile memory may include NAND, NOR, phase change random access memory (PRAM), and magneto-resistive random access memory (MRAM).

The first semiconductor chip 21A has a top surface 21AT at which a first chip pad 22A is disposed and a bottom surface 21AB opposite to the top surface 21AT. The first chip pad 22A is disposed near one of the edges, for example, a left edge of the top surface 21AT of the first semiconductor chip 21A with respect to a first direction FD. The first chip pad 22A is electrically connected to the first integrated circuit.

The first metal pillar 23A is disposed on the first chip pad 22A. The first metal pillar 23A may include copper (Cu). The first metal pillar 23A may be a copper pillar. The first metal pillar 23A has a planar lower surface with a smaller area than the planar area of the upper surface of the first chip pad 22A. The width of the first metal pillar 23A in the first direction FD is smaller or narrower than the width of the first chip pad 22A in the first direction FD. The width of the first chip pad 22A in the first direction FD is W11, the width of the first metal pillar 23A in the first direction FD is W12, and W12 is smaller or narrower than W11.

A first pillar base metal layer 24A is disposed between the first chip pad 22A and the first metal pillar 23A. The first pillar base metal layer 24A electrically connects the first chip pad 22A and the first metal pillar 23A. The first pillar base metal layer 24A can suppress diffusion into the first semiconductor chip 21A of the metal in the first metal pillar 23A. The first pillar base metal layer 24A may include nickel (Ni), titanium nitride (TiN), or palladium (Pd). The first pillar base metal layer 24A may be a nickel layer, a titanium nitride layer, or a stack structure including a nickel layer and a palladium layer.

A second adhesive layer 31B is attached to the bottom surface 21AB of the first semiconductor chip 21A, and the second adhesive layer 31B attaches the first semiconductor chip 21A to a first adhesive layer 31A by.

The second semiconductor chip 21B is offset-stacked on the first semiconductor chip 21A such that the first metal pillar 23A is exposed. The second semiconductor chip 21B is disposed beside the first metal pillar 23A and partially overlaps the first semiconductor chip 21A in the vertical direction VD. The first metal pillar 23A extends substantially in the vertical direction VD and extends beside the second semiconductor chip 21B.

The second semiconductor chip 21B includes a second integrated circuit (not shown). The second integrated circuit may be implemented in various ways depending on the type of the second semiconductor chip 21B. In an embodiment, the second semiconductor chip 21B is a memory die, and the second integrated circuit includes a memory cell.

The second semiconductor chip 21B has a top surface 21BT at which a second chip pad 22B is disposed and a bottom surface 21BB opposite to the top surface 21BT. The second chip pad 22B is disposed near one of the edges, for example, a left edge of the top surface 21BT of the second semiconductor chip 21B with respect to the first direction FD. The second chip pad 22B is electrically connected to the second integrated circuit.

The second metal pillar 23B is disposed on the second chip pad 22B. The second metal pillar 23B may include copper. The second metal pillar 23B may be a copper pillar. The second metal pillar 23B has a planar lower surface with a smaller area than the planar area of the upper surface of the second chip pad 22B. The width of the second metal pillar 23B in the first direction FD is smaller or narrower than the width of the second chip pad 22B in the first direction FD. The width of the second chip pad 22B in the first direction FD is W21, the width of the second metal pillar 23B in the first direction FD is W22, and W22 is smaller or narrower than W21.

A second pillar base metal layer 24B is disposed between the second chip pad 22B and the second metal pillar 23B. The second pillar base metal layer 24B electrically connects the second chip pad 22B and the second metal pillar 23B. The second pillar base metal layer 24B can suppress diffusion into the first semiconductor chip 21A of the metal in the second metal pillar 23B. The second pillar base metal layer 24B may include nickel, titanium nitride, or palladium. The second pillar base metal layer 24B may be a nickel layer, a titanium nitride layer, or a stack structure including a nickel layer and a palladium layer.

A third adhesive layer 31C is disposed between the bottom surface 21BB of the second semiconductor chip 21B and the top surface 21AT of the first semiconductor chip 21A. The third adhesive layer 31C is attached to the bottom surface 21BB of the second semiconductor chip 21B. The third adhesive layer 31C attaches the second semiconductor chip 21B to the first semiconductor chip 21A.

The third semiconductor chip 21C is offset-stacked on the second semiconductor chip 21B such that the second metal pillar 23B is exposed. The third semiconductor chip 21C is offset with respect to the second semiconductor chip 21B in a first direction FD and the second semiconductor chip 21B is offset with respect to the first semiconductor chip 21A in the first direction FD. The third semiconductor chip 21C is disposed beside the second metal pillar 23B and partially overlaps the second semiconductor chip 21B in the vertical direction VD. The second metal pillar 23B extends substantially in the vertical direction VD and extends beside the third semiconductor chip 21C.

The third semiconductor chip 21C includes a third integrated circuit (not shown). The third integrated circuit may be implemented in various ways depending on the type of the third semiconductor chip 21C. In an embodiment, the third semiconductor chip 21C is a memory die, and the third integrated circuit includes a memory cell.

The third semiconductor chip 21C has a top surface 21CT at which a third chip pad 22C is disposed and a bottom surface 21CB opposite to the top surface 21CT. The third chip pad 22C is disposed near one of the edges, for example, a left edge of the top surface 21CT of the third semiconductor chip 21C with respect to the first direction FD. The third chip pad 22C is electrically connected to the third integrated circuit.

The third metal pillar 23C is disposed on the third chip pad 22C. The third metal pillar 23C may include copper. The third metal pillar 23C may be a copper pillar. The third metal pillar 23C has a planar lower surface with a smaller area than the planar area of the upper surface of the third chip pad 22C. The width of the third metal pillar 23C in the first direction FD is smaller or narrower than the width of the third chip pad 22C in the first direction FD. The width of the third chip pad 22C in the first direction FD is W31, the width of the third metal pillar 23C in the first direction FD is W32, and W32 is smaller or narrower than W31.

A third pillar base metal layer 24C is disposed between the third chip pad 22C and the third metal pillar 23C. The third pillar base metal layer 24C electrically connects the third chip pad 22C and the third metal pillar 23C. The third pillar base metal layer 24C can suppress diffusion into the third semiconductor chip 21C of the metal in the third metal pillar 23C. The third pillar base metal layer 24C may include nickel, titanium nitride, or palladium. The third pillar base metal layer 24C may be a nickel layer, a titanium nitride layer, or a stack structure including a nickel layer and a palladium layer.

A fourth adhesive layer 31D is disposed between the bottom surface 21CB of the third semiconductor chip 21C and the top surface 21BT of the second semiconductor chip 21B. The fourth adhesive layer 31D is attached to the bottom surface 21CB of the third semiconductor chip 21C, and the fourth adhesive layer 31D attaches the third semiconductor chip 21C to the second semiconductor chip 21B.

The first inner molding layer 12A is formed to cover the semiconductor chips 21A, 21B, and 21C and surrounds the metal pillars 23A, 23B, and 23C. The first inner molding layer 12A seals the semiconductor chips 21A, 21B, and 21C and the metal pillars 23A, 23B, and 23C. The upper ends of the metal pillars 23A, 23B and 23C are exposed at the top surface of the first inner molding layer 12A. The upper ends or surfaces of the metal pillars 23A, 23B, and 23C are disposed in the same plane as the top surface of the first inner molding layer 12A.

The bottom surface of the first inner molding layer 12A is disposed on substantially the same plane as the bottom surface of the second adhesive layer 31B. The bottom surface of the first inner molding layer 12A and the bottom surface of the second adhesive layer 31B constitute with the bottom surface of the first chip module 20A. The first adhesive layer 31A is disposed between the first chip module 20A and the first outer molding layer 11A. The first adhesive layer 31A is attached to the bottom surface of the first chip module 20A. The first adhesive layer 31A attaches the first chip module 20A to the first outer molding layer 11A.

The first bonding pad 41 is disposed on the first metal pillar 23A. The first bonding pad 41 has a planar lower surface with an area larger than the planar area of the upper surface of the first metal pillar 23A. The width of the first bonding pad 41 in the first direction FD is larger or wider than the width of the first metal pillar 23A in the first direction FD. The first bonding pad 41 is disposed on the top surface of the first metal pillar 23A and the top surface of the first inner molding layer 12A disposed around the first metal pillar 23A.

Referring to FIG. 3, the first bonding pad 41 includes a first barrier metal layer 41A and a first bonding metal layer 41B.

The first barrier metal layer 41A is disposed on the first metal pillar 23A. The first barrier metal layer 41A covers the top surface of the first metal pillar 23A. In an embodiment, the first barrier metal layer 41A is disposed on the top surface of the first metal pillar 23A and the top surface of the first inner molding layer 12A disposed around the first metal pillar 23A.

The first bonding metal layer 41B is disposed on the first barrier metal layer 41A. The first bonding metal layer 41B covers the top surface of the first barrier metal layer 41A. The first barrier metal layer 41A electrically connects the first metal pillar 23A and the first bonding metal layer 41B.

The first bonding wire 51 is disposed on the first bonding pad 41. The first bonding wire 51 extends substantially in the vertical direction VD with one end connected to the first bonding pad 41. The first bonding wire 51 includes a bonding section 51A coupled to the first bonding pad 41 and a vertical section 51B connected to the bonding section 51A. The first bonding wire 51 may include gold.

Heat and ultrasonic energy may be used to bond the first bonding wire 51 to the first bonding pad 41. Heat and ultrasonic energy induce diffusion between metals. Because of induced diffusion, an intermetallic compound (IMC) (not shown) is produced at the interface between the first bonding pad 41 and the first bonding wire 51.

When the intermetallic compound is excessively thick, brittleness increases due to decreased bonding stability, and cracks are likely to occur. The first barrier metal layer 41A may prevent the metal material included in the first metal pillar 23A from diffusing to the interface between the first bonding pad 41 and the first bonding wire 51, thereby suppressing the production of a thick intermetallic compound.

The first barrier metal layer 41A may include nickel or titanium nitride. The first barrier metal layer 41A may be a nickel layer or a titanium nitride layer. The first bonding metal layer 41B may include gold. The first bonding metal layer 41B may be a gold layer. The intermetallic compound may be a nickel-gold compound or a titanium nitride-gold compound.

FIG. 3 illustrates an example where the first barrier metal layer 41A is a single layer including a nickel layer or a titanium nitride layer, although the present disclosure is not limited to this example. The first barrier metal layer 41A may include two or more layers.

Referring to FIG. 4, the first barrier metal layer 41A includes a first layer 41Aa and a second layer 41Ab.

The first layer 41Aa is disposed on the first metal pillar 23A. The first layer 41Aa contacts the top surface of the first metal pillar 23A. In an embodiment, the first layer 41Aa is disposed on the top surface of the first metal pillar 23A and the top surface of the first inner molding layer 12A disposed around the first metal pillar 23A. The first layer 41Aa may include nickel (Ni). The first layer 41Aa may be a nickel layer.

The second layer 41Ab is disposed on the first layer 41Aa. The second layer 41Ab contacts the top surface of the first layer 41Aa. The second layer 41Ab may include palladium (Pd). The second layer 41Ab may be a palladium layer.

Referring to FIG. 1 and FIG. 2, the second bonding pad 42 is disposed on the second metal pillar 23B. The second bonding pad 42 covers the top surface of the second metal pillar 23B. The second bonding pad 42 has a planar lower surface with an area larger than the planar area of the upper surface of the second metal pillar 23B. The width of the second bonding pad 42 in the first direction FD is larger or wider than the width of the second metal pillar 23B in the first direction FD. In an embodiment, the second bonding pad 42 is disposed on the top surface of the second metal pillar 23B and the top surface of the first inner molding layer 12A disposed around the second metal pillar 23B. The second bonding pad 42 has substantially the same structure as the first bonding pad 41. The second bonding pad 42 may be formed including the same material as the first bonding pad 41.

The gap between the first bonding pad 41 and the second bonding pad 42 is larger than the gap between the first metal pillar 23A and the second semiconductor chip 21B. As shown in FIG. 2, the gap between the first metal pillar 23A and the second semiconductor chip 21B is G11, the gap between the first bonding pad 41 and the second bonding pad 42 is G21, and G21 is larger than G11.

The second bonding wire 52 is disposed on the second bonding pad 42. The second bonding wire 52 extends in the vertical direction VD with one end connected to the second bonding pad 42. The second bonding wire 52 may have substantially the same structure as the first bonding wire 51. The second bonding wire 52 may include the same material as the first bonding wire 51. The second bonding wire 52 may include gold.

The third bonding pad 43 is disposed on the third metal pillar 23C. The third bonding pad 43 covers the top surface of the third metal pillar 23C. The third bonding pad 43 has a planar lower surface with an area larger than the planar area of the upper surface of the third metal pillar 23C. The width of the third bonding pad 43 in the first direction FD is larger or wider than the width of the third metal pillar 23C in the first direction FD. In an embodiment, the third bonding pad 43 is disposed on the top surface of the third metal pillar 23C and the top surface of the first inner molding layer 12A disposed around the third metal pillar 23C. The third bonding pad 43 may have substantially the same structure as the first bonding pad 41. The third bonding pad 43 may include the same material as the first bonding pad 41.

The gap between the second bonding pad 42 and the third bonding pad 43 is larger than the gap between the second metal pillar 23B and the third semiconductor chip 21C. As shown in FIG. 2, the gap between the second metal pillar 23B and the third semiconductor chip 21C is G12, the gap between the second bonding pad 42 and the third bonding pad 43 is G22, and G22 is larger than G12.

The third bonding wire 53 is disposed on the third bonding pad 43. The third bonding wire 53 extends in the vertical direction VD with one end connected to the third bonding pad 43. The third bonding wire 53 may have substantially the same structure as the first bonding wire 51. The third bonding wire 53 may include the same material as the first bonding wire 51. The third bonding wire 53 may include gold.

The second chip module 20B is disposed on the first chip module 20A. The second chip module 20B is offset in the first direction FD with respect to the first chip module 20A. The second chip module 20B is offset in the first direction FD with respect to the first chip module 20A. and the second semiconductor chip 21B is offset in the first direction FD with respect to the first semiconductor chip 21A, and the third semiconductor chip 21C is offset in the first direction FD with respect to the second semiconductor chip 21B.

The second chip module 20B includes a fourth semiconductor chip 21D, a fifth semiconductor chips 21E, and a sixth semiconductor chip 21F, a fourth metal pillar 23D, a fifth metal pillar 23E, a sixth metal pillar 23F, and a second inner molding layer 12B.

The fifth semiconductor chip 21E is stacked on the fourth semiconductor chip 21D, and the sixth semiconductor chip 21F is stacked on the fifth semiconductor chip 21E. In FIG. 1, the second chip module 20B includes three semiconductor chips, although the present disclosure is not limited to this example. The number of semiconductor chips included in the second chip module 20B may be two or more.

Referring to FIG. 1 and FIG. 5, the fourth semiconductor chip 21D includes a fourth integrated circuit (not shown). The fourth integrated circuit may be implemented in various ways depending on the type of the fourth semiconductor chip 21D. In an embodiment, the fourth semiconductor chip 21D is a memory die, and the fourth integrated circuit includes a memory cell.

The fourth semiconductor chip 21D has a top surface 21DT at which a fourth chip pad 22D is disposed and a bottom surface 21DB opposite to the top surface 21DT. The fourth chip pad 22D is disposed near one of the edges, for example, a right edge of the top surface 21DT of the fourth semiconductor chip 21D with respect to the first direction FD. The fourth chip pad 22D is electrically connected to the fourth integrated circuit.

The fourth metal pillar 23D is disposed on the fourth chip pad 22D. The fourth metal pillar 23D may include copper. The fourth metal pillar 23D may be a copper pillar. The fourth metal pillar 23D has a planar lower surface with an area smaller than the planar area of the upper surface of the fourth chip pad 22D. The width of the fourth metal pillar 23D in the first direction FD is smaller or narrower than the width of the fourth chip pad 22D in the first direction FD. The width of the fourth chip pad 22D in the first direction FD is W41, the width of the fourth metal pillar 23D in the first direction FD is W42, and W42 is smaller or narrower than W41.

A fourth pillar base metal layer 24D is disposed between the fourth chip pad 22D and the fourth metal pillar 23D. The fourth pillar base metal layer 24D electrically connects the fourth chip pad 22D and the fourth metal pillar 23D. The fourth pillar base metal layer 24D can suppress diffusion into the fourth semiconductor chip 21D of the metal included in the fourth metal pillar 23D. The fourth pillar base metal layer 24D may include nickel, titanium nitride, or palladium. The fourth pillar base metal layer 24D may be a nickel layer, a titanium nitride layer, or a stack structure including a nickel layer and a palladium layer.

A sixth adhesive layer 31F is disposed between the bottom surface 21DB of the fourth semiconductor chip 21D and a fifth adhesive layer 31E. The sixth adhesive layer 31F is attached to the bottom surface 21DB of the fourth semiconductor chip 21D. The sixth adhesive layer 31F attaches the fourth semiconductor chip 21D to the fifth adhesive layer 31E.

The fifth semiconductor chip 21E includes a fifth integrated circuit (not shown). The fifth integrated circuit may be implemented in various ways depending on the type of the fifth semiconductor chip 21E. In an embodiment, the fifth semiconductor chip 21E is a memory die, and the fifth integrated circuit includes a memory cell.

The fifth semiconductor chip 21E is offset-stacked on the fourth semiconductor chip 21D such that the fourth metal pillar 23D is exposed. The fifth semiconductor chip 21E is offset with respect to the fourth semiconductor chip 21D in a direction opposite to the first direction FD in which the second chip module 20B is offset with respect to the first chip module 20A. The fifth semiconductor chip 21E is disposed beside the fourth metal pillar 23D and partially overlaps the fourth semiconductor chip 21D in the vertical direction VD. The fourth metal pillar 23D extends in the vertical direction VD and extends beside the fifth semiconductor chip 21E.

The fifth semiconductor chip 21E has a top surface 21ET at which a fifth chip pad 22E is disposed and a bottom surface 21EB opposite to the top surface 21ET. The fifth chip pad 22E is disposed near one of the edges, for example, a right edge of the top surface 21ET of the fifth semiconductor chip 21E with respect to the first direction FD. The fifth chip pad 22E is electrically connected to the fifth integrated circuit.

The fifth metal pillar 23E is disposed on the fifth chip pad 22E. The fifth metal pillar 23E may include copper. The fifth metal pillar 23E may be a copper pillar. The fifth metal pillar 23E has a planar lower surface with a smaller area than the planar area of the upper surface of the fifth chip pad 22E. The width of the fifth metal pillar 23E in the first direction FD is smaller or narrower than the width of the fifth chip pad 22E in the first direction FD. The width of the fifth chip pad 22E in the first direction FD is W51, the width of the fifth metal pillar 23E in the first direction FD is W52, and W52 is smaller or narrower than W51.

A fifth pillar base metal layer 24E is disposed between the fifth chip pad 22E and the fifth metal pillar 23E. The fifth pillar base metal layer 24E electrically connects the fifth chip pad 22E and the fifth metal pillar 23E. The fifth pillar base metal layer 24E can suppress diffusion into the fifth semiconductor chip 21E of the metal in the fifth metal pillar 23E. The fifth pillar base metal layer 24E may include nickel, titanium nitride, or palladium. The fifth pillar base metal layer 24E may be a nickel layer, a titanium nitride layer, or a stack structure including a nickel layer and a palladium layer.

A seventh adhesive layer 31G is disposed between the bottom surface 21EB of the fifth semiconductor chip 21E and the top surface 21DT of the fourth semiconductor chip 21D. The seventh adhesive layer 31G is attached to the bottom surface 21EB of the fifth semiconductor chip 21E. The seventh adhesive layer 31G attaches the fifth semiconductor chip 21E to the fourth semiconductor chip 21D by.

The sixth semiconductor chip 21F is offset-stacked on the fifth semiconductor chip 21E such that the fifth metal pillar 23E is exposed. The sixth semiconductor chip 21F is offset with respect to the fifth semiconductor chip 21E in the same direction that the fifth semiconductor chip 21E is offset with respect to the fourth semiconductor chip 21D. The sixth semiconductor chip 21F is disposed beside the fifth metal pillar 23E and partially overlaps the fifth semiconductor chip 21E in the vertical direction VD. The fifth metal pillar 23E extends in the vertical direction VD and extends beside the sixth semiconductor chip 21F.

The sixth semiconductor chip 21F includes a sixth integrated circuit (not shown). The sixth integrated circuit may be implemented in various ways depending on the type of the sixth semiconductor chip 21F. In an embodiment, the sixth semiconductor chip 21F is a memory die, and the sixth integrated circuit includes a memory cell.

The sixth semiconductor chip 21F has a top surface 21FT at which a sixth chip pad 22F is disposed and a bottom surface 21FB opposite to the top surface 21FT. The sixth chip pad 22F is disposed near one of the edges, for example, a right edge of the top surface 21FT of the sixth semiconductor chip 21F with respect to the first direction FD. The sixth chip pad 22F is electrically connected to the sixth integrated circuit.

The sixth metal pillar 23F is disposed on the sixth chip pad 22F. The sixth metal pillar 23F may include copper. The sixth metal pillar 23F may be a copper pillar. The sixth metal pillar 23F has a planar lower surface with a smaller area than the planar area of the upper surface of the sixth chip pad 22F. The width of the sixth metal pillar 23F in the first direction FD is smaller or narrower than the width of the sixth chip pad 22F in the first direction FD. The width of the sixth chip pad 22F in the first direction FD is W61, the width of the sixth metal pillar 23F in the first direction FD is W62, and W62 is smaller or narrower than W61.

A sixth pillar base metal layer 24F is disposed between the sixth chip pad 22F and the sixth metal pillar 23F. The sixth pillar base metal layer 24F electrically connects the sixth chip pad 22F and the sixth metal pillar 23F. The sixth pillar base metal layer 24F can suppress diffusion into the sixth semiconductor chip 21F of the metal included in the sixth metal pillar 23F. The sixth pillar base metal layer 24F may include nickel, titanium nitride, or palladium. The sixth pillar base metal layer 24F may be a nickel layer, a titanium nitride layer, or a stack structure including a nickel layer and a palladium layer.

An eighth adhesive layer 31H is disposed between the bottom surface 21FB of the sixth semiconductor chip 21F and the top surface 21ET of the fifth semiconductor chip 21E. The eighth adhesive layer 31H is attached to the bottom surface 21FB of the sixth semiconductor chip 21F. The eighth adhesive layer 31H attaches the sixth semiconductor chip 21F to the fifth semiconductor chip 21E.

The second inner molding layer 12B is formed to cover the semiconductor chips 21D, 21E, and 21F and surrounds the metal pillars 23D, 23E, and 23F. The second inner molding layer 12B seals the semiconductor chips 21D, 21E, and 21F and the metal pillars 23D, 23E, and 23F. The upper ends of the metal pillars 23D, 23E, and 23F are exposed at the top surface of the second inner molding layer 12B. The upper ends or surfaces of the metal pillars 23D, 23E, and 23F are disposed in substantially the same plane as the top surface of the second inner molding layer 12B. The bottom surface of the second inner molding layer 12B is disposed on substantially the same plane as the bottom surface of the sixth adhesive layer 31F.

Referring to FIG. 1, the bottom surface of the second inner molding layer 12B and the bottom surface of the sixth adhesive layer 31F constitute the bottom surface of the second chip module 20B. The fifth adhesive layer 31E is disposed between the bottom surface of the second chip module 20B and the first chip module 20A. The fifth adhesive layer 31E is attached to the bottom surface of the second chip module 20B. The fifth adhesive layer 31E attaches the second chip module 20B to the first chip module 20A.

The second outer molding layer 11B is formed on the first outer molding layer 11A to cover the first chip module 20A and the bonding pads 41, 42, and 43 and surround the bonding wires 51, 52, and 53 and the second chip module 20B. The second outer molding layer 11B seals the chip modules 20A and 20B, the bonding pads 41, 42, and 43, and the bonding wires 51, 52, and 53 to protect the chip modules 20A and 20B, the bonding pads 41, 42, and 43, and the bonding wires 51, 52 and 53 from the external environment. The coefficient of thermal expansion (CTE) of the second outer molding layer 11B may be the same as the coefficient of thermal expansion of the inner molding layers 12A and 12B. The Young’s modulus of the second outer molding layer 11B may be the same as the Young’s modulus of the inner molding layers 12A and 12B. The second outer molding layer 11B may include the same material as the inner molding layers 12A and 12B.

The upper ends of the bonding wires 51, 52, and 53, the upper ends of the metal pillars 23D, 23E, and 23F, and the top surface of the second inner molding layer 12B are exposed at the top surface of the second outer molding layer 11B. The upper ends of the bonding wires 51, 52, and 53, the upper ends of the metal pillars 23D, 23E, and 23F, and the top surface of the second inner molding layer 12B are disposed in substantially the same plane as the top surface of the second outer molding layer 11B.

The redistribution layer 60 is disposed on the upper ends of the bonding wires 51, 52, and 53, the upper ends of the metal pillars 23D, 23E, and 23F, the top surface of the second inner molding layer 12B, and the top surface of the second outer molding layer 11B.

The redistribution layer 60 includes a first redistribution pad 61A to a sixth redistribution pad 61F, redistribution patterns 64, and dielectric layers also referred to as a redistribution insulating layer 63.

Referring to FIG. 1 and FIG. 6, the first redistribution pad 61A is disposed on the first bonding wire 51. A lower surface of the first redistribution pad 61A has a larger area than the area of the upper surface of the first bonding wire 51. The first redistribution pad 61A covers the first bonding wire 51 and the second outer molding layer 11B disposed around the first bonding wire 51. The first redistribution pad 61A may include copper. The first redistribution pad 61A may be a copper layer.

A first pad base metal layer 62A is disposed between the first bonding wire 51 and the first redistribution pad 61A. The first pad base metal layer 62A is disposed on the first bonding wire 51 and the second outer molding layer 11B under the first redistribution pad 61A. The first pad base metal layer 62A electrically connects the first bonding wire 51 and the first redistribution pad 61A. The first pad base metal layer 62A may include titanium (Ti) or titanium nitride. The first pad base metal layer 62A may be a titanium layer or a titanium nitride layer.

The second redistribution pad 61B is disposed on the second bonding wire 52. A lower surface of the second redistribution pad 61B has a larger planar area than the area of the upper surface of the second bonding wire 52. The second redistribution pad 61B is disposed on the second bonding wire 52 and the second outer molding layer 11B disposed around the second bonding wire 52. The second redistribution pad 61D may include copper. The second redistribution pad 61B may be a copper layer.

A second pad base metal layer 62B is disposed between the second bonding wire 52 and the second redistribution pad 61B. The second pad base metal layer 62B is disposed on the second bonding wire 52 and the second outer molding layer 11B under the second redistribution pad 61B. The second pad base metal layer 62B electrically connects the second bonding wire 52 and the second redistribution pad 61B. The second pad base metal layer 62B may include titanium or titanium nitride. The second pad base metal layer 62B may be a titanium layer or a titanium nitride layer.

The third redistribution pad 61C is disposed on the third bonding wire 53. A lower surface of the third redistribution pad 61C has a larger planar area than the area of the upper surface of the third bonding wire 53. The third redistribution pad 61C is disposed on the third bonding wire 53 and the second outer molding layer 11B disposed around the third bonding wire 53. The third redistribution pad 61C may include copper. The third redistribution pad 61C may be a copper layer.

A third pad base metal layer 62C is disposed between the third bonding wire 53 and the third redistribution pad 61C. The third pad base metal layer 62C is disposed on the third bonding wire 53 and the second outer molding layer 11B under the third redistribution pad 61C. The third pad base metal layer 62C electrically connects the third bonding wire 53 and the third redistribution pad 61C. The third pad base metal layer 62C may include titanium or titanium nitride. The third pad base metal layer 62C may be a titanium layer or a titanium nitride layer.

Referring to FIG. 1 and FIG. 5, the fourth redistribution pad 61D is disposed on the fourth metal pillar 23D. A lower surface of the fourth redistribution pad 61D has a larger planar area than the planar area of the upper surface of the fourth metal pillar 23D. The width of the fourth redistribution pad 61D in the first direction FD is larger or wider than the width of the fourth metal pillar 23D in the first direction FD. The fourth redistribution pad 61D is disposed on the fourth metal pillar 23D and the second inner molding layer 12B disposed around the fourth metal pillar 23D. The fourth redistribution pad 61D may include copper. The fourth redistribution pad 61D may be a copper layer.

A fourth pad base metal layer 62D is disposed between the fourth metal pillar 23D and the fourth redistribution pad 61D. The fourth pad base metal layer 62D is disposed on the fourth metal pillar 23D and the second inner molding layer 12B under the fourth redistribution pad 61D. The fourth pad base metal layer 62D electrically connects the fourth metal pillar 23D and the fourth redistribution pad 61D. The fourth pad base metal layer 62D may include titanium or titanium nitride. The fourth pad base metal layer 62D may be a titanium layer or a titanium nitride layer.

The fifth redistribution pad 61E is disposed on the fifth metal pillar 23E. A lower surface of the fifth redistribution pad 61E has a larger planar area than the planar area of the upper surface of the fifth metal pillar 23E. The width of the fifth redistribution pad 61E in the first direction FD is larger or wider than the width of the fifth metal pillar 23E in the first direction FD. The fifth redistribution pad 61E covers the fifth metal pillar 23E and the second inner molding layer 12B disposed around the fifth metal pillar 23E. The fifth redistribution pad 61E may include copper. The fifth redistribution pad 61E may be a copper layer.

A fifth pad base metal layer 62E is disposed between the fifth metal pillar 23E and the fifth redistribution pad 61E. The fifth pad base metal layer 62E is disposed on the fifth metal pillar 23E and the second inner molding layer 12B under the fifth redistribution pad 61E. The fifth pad base metal layer 62E electrically connects the fifth metal pillar 23E and the fifth redistribution pad 61E. The fifth pad base metal layer 62E may include titanium or titanium nitride. The fifth pad base metal layer 62E may be a titanium layer or a titanium nitride layer.

The sixth redistribution pad 61F is disposed on the sixth metal pillar 23F. A lower surface of the sixth redistribution pad 61F has a larger planar area than the planar area of the upper surface of the sixth metal pillar 23F. The width of the sixth redistribution pad 61F in the first direction FD is larger or wider than the width of the sixth metal pillar 23F in the first direction FD. The sixth redistribution pad 61F is disposed on the sixth metal pillar 23F and the second inner molding layer 12B disposed around the sixth metal pillar 23F. The sixth redistribution pad 61F may include copper. The sixth redistribution pad 61F may be a copper layer.

A sixth pad base metal layer 62F is disposed between the sixth metal pillar 23F and the sixth redistribution pad 61F. The sixth pad base metal layer 62F is disposed on the sixth metal pillar 23F and the second inner molding layer 12B under the sixth redistribution pad 61F. The sixth pad base metal layer 62F electrically connects the sixth metal pillar 23F and the sixth redistribution pad 61F. The sixth pad base metal layer 62F may include titanium or titanium nitride. The sixth pad base metal layer 62F may be a titanium layer or a titanium nitride layer.

The redistribution patterns 64 are connected to at least one of the redistribution pads 61A to 61F and are connected to the semiconductor chips 21A to 21F through the redistribution pads 61A to 61F, the bonding wires 51, 52, and 53, and the metal pillars 23A to 23F. The redistribution patterns 64 are insulated from each other by the dielectric layers 63.

Some of the redistribution patterns 64 include under bump metallurgy (UBM) 64A. An external connection terminal 70 is connected to the UBM 64A. The UBM 64A is a wetting layer that facilitates sufficient adherence to the external connection terminal 70. The external connection terminal 70 may include a solder ball.

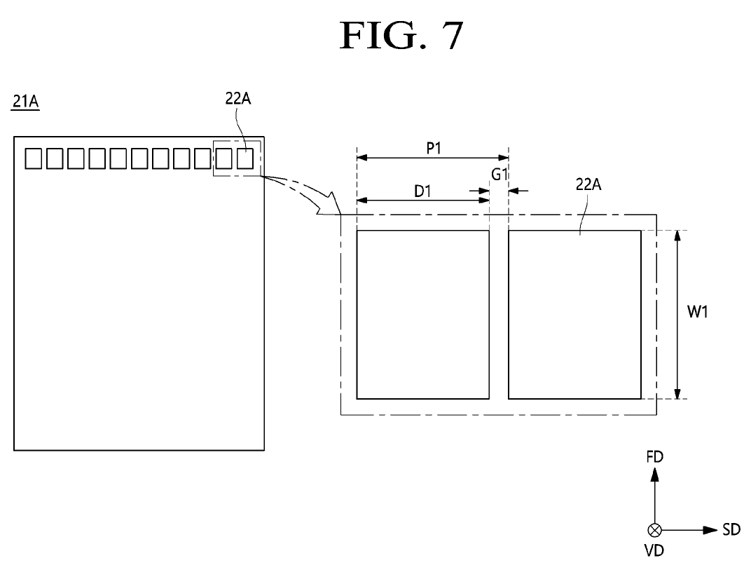

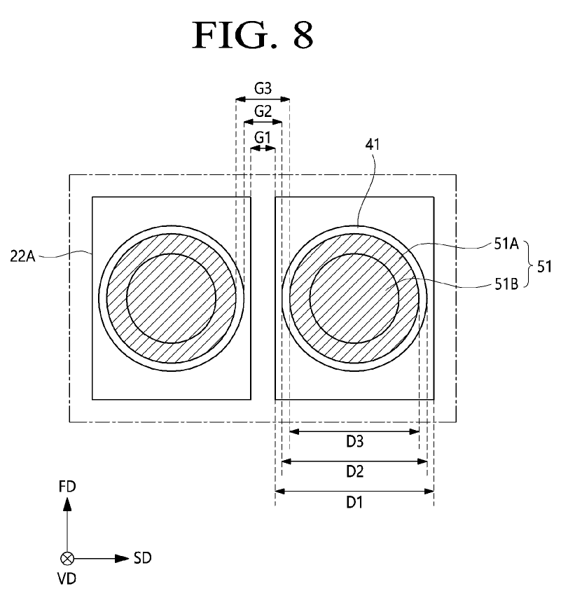

FIG. 7 is a plan view of the first semiconductor chip, for example, as shown in FIG. 1, and FIG. 8 is a plan view illustrating first chip pads, first metal pillars, and first bonding wires.

Referring to FIG. 7, a plurality of first chip pads 22A are disposed near one of the edges of the first semiconductor chip 21A with respect to the first direction FD. As illustrated in the example of FIG. 7, the first chip pads 22A are disposed in a line in a second direction SD, although the present disclosure is not limited to this example.

The first chip pad 22A may have a quadrangular or rectangular shape. The first chip pad 21A has a length of D1 in the second direction SD and a width of W1 in the first direction FD. D1 may be different from W1. As illustrated in FIG. 7, W1 is larger than D1. In an embodiment, D1 has the same measurement as W1.

The plurality of first chip pads 22A are disposed at a pitch of P1 in the second direction SD. P1 is the sum of the length of the first chip pad 22A in the second direction SD and the gap between consecutive or neighboring first chip pads 22A. The length of the first chip pad 22A in the second direction FD is D1, the gap between neighboring first chip pads 22A is G1, and P1 is the sum of D1 and G1.

The semiconductor chips 21B and 21C, such shown in FIG. 1, may have the same shape as the first semiconductor chip 21A. The semiconductor chips 21D, 21E, and 21F, such as shown in FIG. 1, may have a structure that is rotated 180 degrees relative to the first semiconductor chip 21A in the first direction FD.

Referring to FIG. 8, the planar shape of the first metal pillar 23A and the first bonding pad 41 is circular. The present disclosure is not limited to these examples, and the planar shape of the first metal pillar 23A and the first bonding pad 41 may have other shapes such as a quadrangle, a hexagon, a polygon, or an ellipse.

The lower surface of the first bonding pad 41 has a smaller planar area than the planar area of the upper surface of the first chip pad 22A. The length of the first bonding pad 41 in the second direction SD is smaller or shorter than the length of the first chip pad 22A in the second direction SD. As shown in FIG. 8, the length of the first chip pad 22A in the second direction SD is D1, the length of the first bonding pad 41 in the second direction SD is D2, and D2 is smaller than D1.

The gap between consecutive or neighboring first bonding pads 41 is larger than the gap between consecutive or neighboring first chip pads 22A. As shown in FIG. 8, The gap between neighboring first chip pads 22A is G1, the gap between neighboring first bonding pads 41 is G2, and G2 is larger than G1.

As described with reference to FIG. 3, the first bonding wire 51 includes the bonding section 51A and the vertical section 51B connected to the bonding section 51A.

The lower surface of the bonding section 51A of the first bonding wire 51 has a smaller planar area than the upper surface of the first bonding pad 41. As shown in FIG. 8, the length of the bonding section 51A of the first bonding wire 51 in the second direction SD is smaller than the length of the first bonding pad 41 in the second direction SD. As shown in FIG. 8, the length of the first bonding pad 41 in second direction SD is D2, the length of the bonding section 51A of the first bonding wire 51 in the second direction SD is D3, and D3 is smaller than D2.

The gap between the bonding sections 51A of consecutive or neighboring first bonding wires 51 is larger than the gap between consecutive or neighboring first bonding pads 41. As shown in FIG. 8, the gap between neighboring first bonding pads 41 is G2, the gap between the bonding sections 51A of neighboring first bonding wires 51 is G3, and G3 is larger than G2.

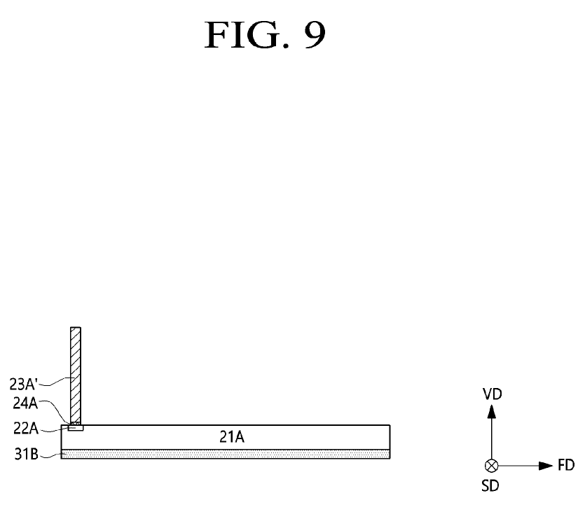

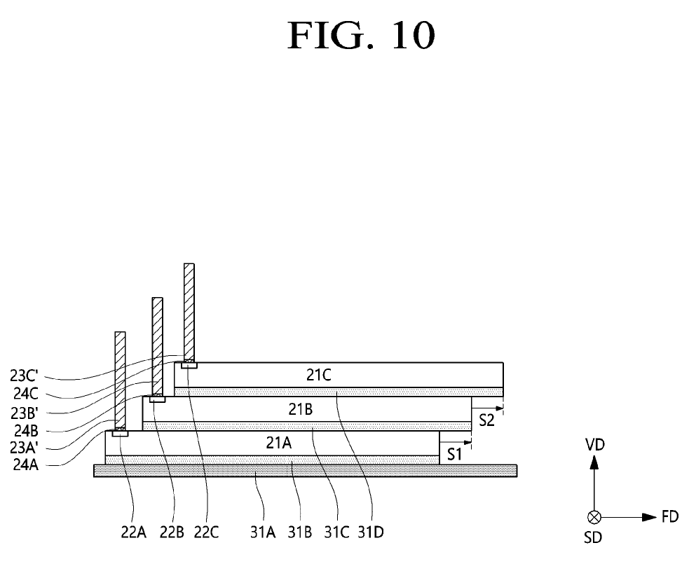

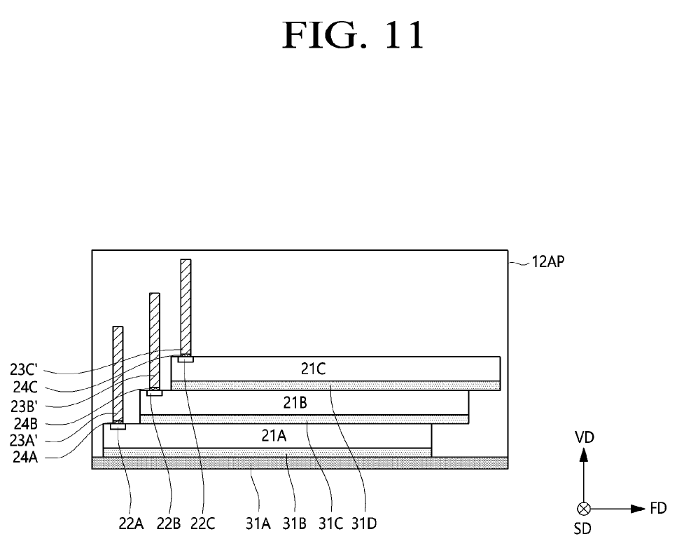

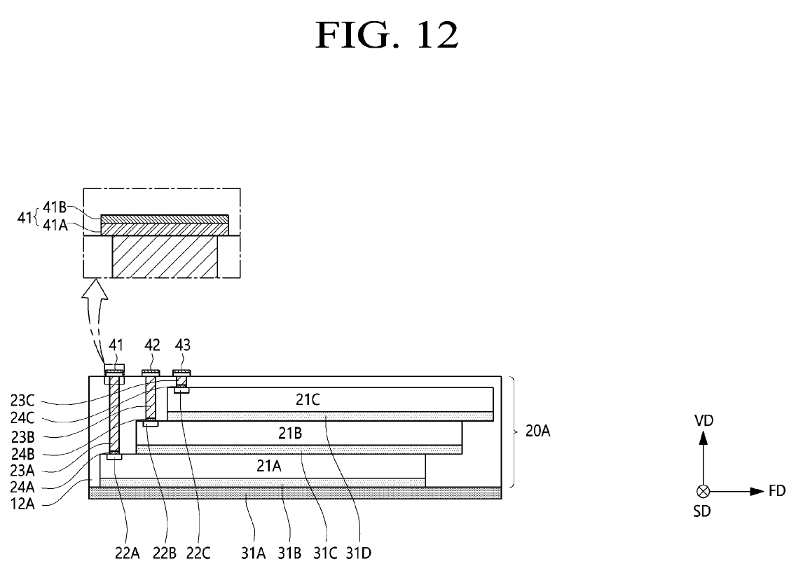

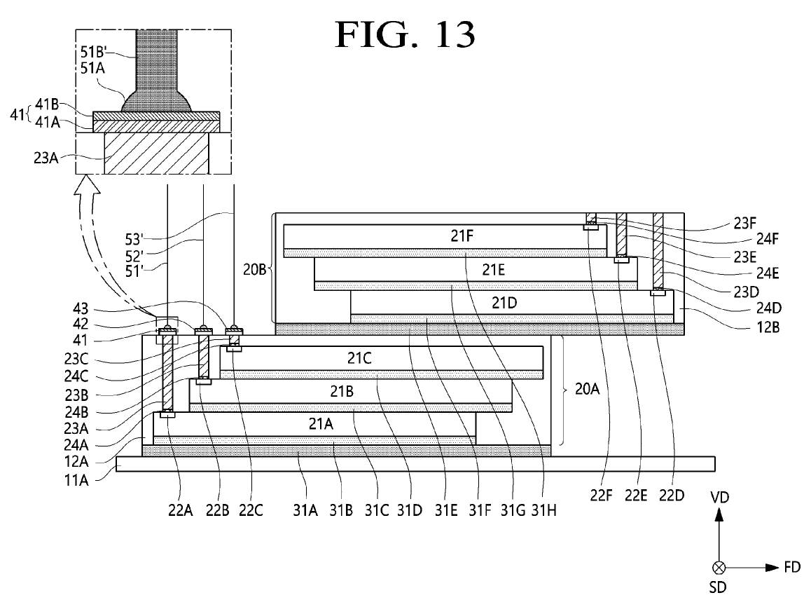

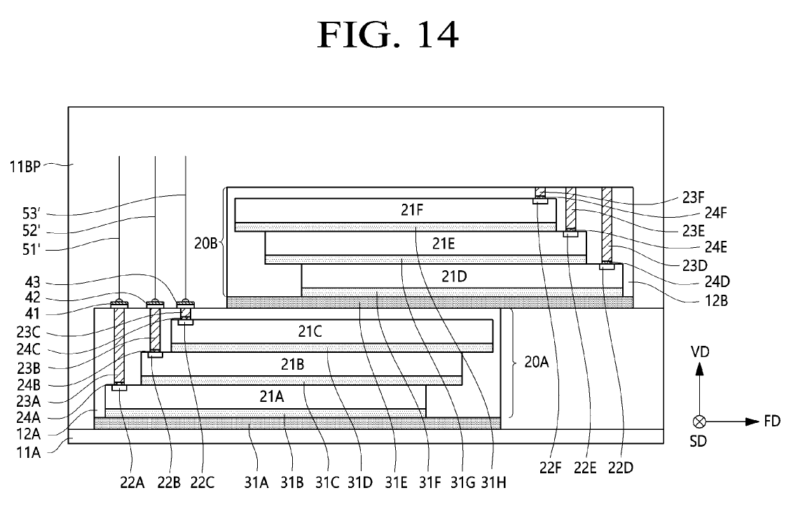

FIG. 9- FIG. 15 are cross-sectional views of a semiconductor package utilizing a method of manufacturing a semiconductor package according to an embodiment of the present disclosure.

Referring to FIG. 9, a first metal pillar 23A’ is formed on a first chip pad 22A of a first semiconductor chip 21A.

A process of forming the first metal pillar 23A’ may include forming a seed metal layer on the first semiconductor chip 21A, forming, on the seed metal layer, a plating resist pattern having an opening that provides a template for the first metal pillar 23A’, forming a metal bump in the opening of the plating resist pattern, removing the plating resist pattern, and removing the seed metal layer that does not overlap the metal bump.

The seed metal layer may be formed by a deposition method such as sputtering. The metal bump may be grown by an electrolytic plating process. The seed metal layer and the metal bump include copper (Cu). The first metal pillar 23A’ includes the seed metal layer and the metal bump that is grown on the seed metal layer. The height of the first metal pillar 23A’ in the vertical direction VD is larger than the thickness of the first semiconductor chip 21A in the vertical direction VD.

A first pillar base metal layer 24A may be formed by forming a base metal layer on the first semiconductor chip 21A before forming the seed metal layer and by, after removing the seed metal layer that does not overlap the metal bump, etching the base metal layer exposed by the removal of the seed metal layer. The base metal layer may be formed by a deposition method such as sputtering. The base metal layer may include nickel, titanium nitride, or palladium. The base metal layer may be a nickel layer, a titanium nitride layer, or a stack structure including a nickel layer and a palladium layer. A second adhesive layer 31B is attached to the bottom surface of the first semiconductor chip 21A that is opposite to the top surface of the first semiconductor chip 21A at which the first chip pad 22A is disposed.

Referring to FIG. 10, the first semiconductor chip 21A that is formed with the first metal pillar 23A’ is disposed on a first adhesive layer 31A. The second adhesive layer 31B attaches the first semiconductor chip 21A to the first adhesive layer 31A.

The first adhesive layer 31A may be attached to a carrier substrate (not shown). Processes utilized during manufacturing of a first chip module of a semiconductor package according to the embodiment may be performed on the carrier substrate.

A second semiconductor chip 21B formed with a second metal pillar 23B’ is stacked on the first semiconductor chip 21A. A second pillar base metal layer 24B is disposed between the second metal pillar 23B’ and the second semiconductor chip 21B. The second semiconductor chip 21B is offset with respect to the first semiconductor chip 21A in the first direction FD such that the first metal pillar 23A’ is exposed. The second semiconductor chip 21B is offset by a first distance S1 from the first semiconductor chip 21A. A third adhesive layer 31C attaches the second semiconductor chip 21B to the first semiconductor chip 21A.

A third semiconductor chip 21C formed with a third metal pillar 23C’ is stacked on the second semiconductor chip 21B. A third pillar base metal layer 24C is disposed between the third metal pillar 23C’ and the third semiconductor chip 21C. The third semiconductor chip 21C is offset with respect to the second semiconductor chip 21B in the first direction FD such that the second metal pillar 23B’ is exposed. The third semiconductor chip 21C is offset with respect to the second semiconductor chip 21B in the first direction FD and the second semiconductor chip 21B is offset with respect to the first semiconductor chip 21A in the first direction FD. The third semiconductor chip 21C is offset by a second distance S2 from the second semiconductor chip 21B. The second distance S2 may be substantially the same as the first distance S1. A fourth adhesive layer 31D attaches the third semiconductor chip 21C to the second semiconductor chip 21B.

Referring to FIG. 11, a first pre-inner molding layer 12AP is formed.

The first pre-inner molding layer 12AP is formed to cover the semiconductor chips 21A, 21B, and 21C and the metal pillars 23A’, 23B’, and 23C’. The first pre-inner molding layer 12AP is a pre-structure that forms a first inner molding layer 12A such as shown in FIG. 12 and has a height taller or larger than the height of the first inner molding layer 12A (see FIG. 12).

The first pre-inner molding layer 12AP may be formed by a molding process using a liquid sealant. The molding process may include mounting, in a mold (not shown), the carrier substrate on which the semiconductor chips 21A, 21B, and 21C and the metal pillars 23A’, 23B’, and 23C’ are disposed, introducing a liquid sealant into the mold, and curing the introduced sealant. The sealant may include an EMC.

Referring to FIG. 12, the first inner molding layer 12A is formed by thinning the first pre-inner molding layer 12AP of FIG. 11, and the bonding pads 41, 42, and 43 are formed.

The thinning process may include a chemical mechanical polishing (CMP) process or a grinding process. During the thinning process, the metal pillars 23A’, 23B’, and 23C’ of FIG. 11 are polished along with the first pre-inner molding layer 12AP of FIG. 11. During the thinning process, the upper ends of metal pillars 23A, 23B, and 23C are exposed at the top surface of the first inner molding layer 12A. The upper ends of the metal pillars 23A, 23B, and 23C are disposed on substantially the same plane as the top surface of the first inner molding layer 12A. A first chip module 20A including semiconductor chips 21A, 21B, and 21C, the metal pillars 23A, 23B, and 23C, and the first inner molding layer 12A is formed.

The bonding pads 41, 42, and 43 are formed on the metal pillars 23A, 23B, and 23C, respectively. The first bonding pad 41 may have a structure in which a first barrier metal layer 41A and a first bonding metal layer 41B are stacked. The first barrier metal layer 41A may be formed by a deposition process such as a sputtering process. The first barrier metal layer 41A may include a nickel layer, a titanium nitride layer, or a stack structure including a nickel layer and a palladium layer. The first bonding metal layer 41B may be formed by an electrolytic plating process or an electroless process. In an embodiment, the lower surface of the first bonding pad 41 has a planar area larger than the planar area of the upper surface of the first metal pillar 23A. In an embodiment, the width of the first bonding pad 41 in the first direction FD is wider or larger than the width of the first metal pillar 23A in the first direction FD. The bonding pads 42 and 43 may be formed along with the first bonding pad 41. Each of the bonding pads 42 and 43 may have a structure similar to the structure of the first bonding pad 41. The second and third bonding pads 42 and 43 may include the same material as the first bonding pad 41.

Referring to FIG. 13, a second chip module 20B is stacked on the first chip module 20A and the bonding wires 51’, 52’ and 53’ are formed.

The second chip module 20B may be produced using the same method as the first chip module 20A. The second chip module 20B may be formed at the same time the first chip module 20A is formed. The second chip module 20B has a structure that is symmetrical to the first chip module 20A in the first direction FD. The second chip module 20B is rotated 180 degrees and disposed on the first chip module 20A.

The second chip module 20B includes the semiconductor chips 21D, 21E, and 21F, the metal pillars 23D, 23E, and 23F, and a second inner molding layer 12B. A fifth adhesive layer 31E attaches the second chip module 20B to the first chip module 20A. The second chip module 20B is offset with respect to the first chip module 20A in the first direction FD. The second chip module 20B is offset with respect to the first chip module 20A in the first direction FD that is the same direction as the direction the second semiconductor chip 21B is offset with respect to the first semiconductor chip 21A and the direction the third semiconductor chip 21C is offset with respect to the second semiconductor chip 21B.

A sixth adhesive layer 31F attaches the fourth semiconductor chip 21D to the fifth adhesive layer 31E. The fourth metal pillar 23D is disposed on a fourth chip pad 22D of the fourth semiconductor chip 21D. A fourth pillar base metal layer 24D is disposed between the fourth chip pad 22D of the fourth semiconductor chip 21D and the fourth metal pillar 23D.

The fifth semiconductor chip 21E is offset-stacked on the fourth semiconductor chip 21D such that the fourth metal pillar 23D is exposed. The fifth semiconductor chip 21E is offset with respect to the fourth semiconductor chip 21D in a direction opposite to the direction the second chip module 20B is offset with respect to the first chip module 20A. A seventh adhesive layer 31G attaches the fifth semiconductor chip 21E to the fourth semiconductor chip 21D. The fifth metal pillar 23E is disposed on a fifth chip pad 22E of the fifth semiconductor chip 21E. A fifth pillar base metal layer 24E is disposed between the fifth chip pad 22E of the fifth semiconductor chip 21E and the fifth metal pillar 23E.

The sixth semiconductor chip 21F is offset-stacked on the fifth semiconductor chip 21E such that the fifth metal pillar 23E is exposed. The sixth semiconductor chip 21F is offset with respect to the fifth semiconductor chip 21E in a direction is opposite to the direction the second chip module 20B is offset with respect to the first chip module 20A. An eighth adhesive layer 31H attaches the sixth semiconductor chip 21F to the fifth semiconductor chip 21E. The sixth metal pillar 23F is disposed on a sixth chip pad 22F of the sixth semiconductor chip 21F. A sixth pillar base metal layer 24F is disposed between the sixth chip pad 22F of the sixth semiconductor chip 21F and the sixth metal pillar 23F.

The second inner molding layer 12B is formed to cover the semiconductor chips 21D, 21E, and 21F and surround the metal pillars 23D, 23E, and 23F. The upper ends of the metal pillars 23D, 23E and 23F are exposed at the top surface of the second inner molding layer 12B. The upper ends of the metal pillars 23D, 23E, and 23F are disposed in the same plane as the top surface of the second inner molding layer 12B. The bottom surface of the second inner molding layer 12B is disposed in substantially the same plane as the bottom surface of the sixth adhesive layer 31F.

The bonding wires 51’, 52’, and 53’ are connected to the bonding pads 41, 42, and 43, respectively. The bonding wires 51’, 52’, and 53’ may be formed of a conductive material. The conductive material may include gold.

The first bonding wire 51’ may be formed by a wire bonding process using a wire bonding device (not shown). In detail, the first bonding wire 51' may be formed by forming a bonding ball at one end of a metal wire using the capillary of the wire bonding device, bonding the formed bonding ball to the first bonding pad 41, pulling the other end of the metal wire in the vertical direction VD away from the first bonding pad 41, for example, from a bottom end to an upper end, such that the upper end of the metal wire extends to a desired position, and the upper end of the metal wire is cut. The first bonding wire 51’ includes a bonding section 51A that is bonded to the first bonding pad 41 and a vertical section 51B’ that extends from the bonding section 51A in the vertical direction VD.

Using a method similar to the method used to form the first bonding wire 51’, the second bonding wire 52’ is formed on the second bonding pad 42, and the third bonding wire 53’ is formed on the third bonding pad 43. Each of the bonding wires 52’ and 53’ includes a bonding section and a vertical section similar to the first bonding wire 51’ .

Referring to FIG. 14, a second pre-outer molding layer 11BP is formed.

The second pre-outer molding layer 11BP is formed to cover the chip modules 20A and 20B, the bonding pads 41, 42, and 43 and the bonding wires 51’, 52’, and 53’. The second pre-outer molding layer 11BP is a pre-structure that forms a second outer molding layer 11B of FIG. 15 and is formed having a height taller or larger than the height of the second outer molding layer 11B of FIG. 15.

The second pre-outer molding layer 11BP may be formed by a molding process using a liquid sealant. The molding process may include mounting, in a mold (not shown), the first outer molding layer 11A on which the chip modules 20A and 20B, the bonding pads 41, 42, and 43 and the bonding wires 51', 52’, and 53' are disposed, introducing a liquid sealant into the mold, and curing the introduced sealant. The sealant may include an EMC.

Referring to FIG. 15, the second outer molding layer 11B is formed by thinning the second pre-outer molding layer 11BP of FIG. 14.

The thinning process may include a chemical mechanical polishing (CMP) process or a grinding process. During the thinning process, the bonding wires 51’, 52’, and 53’are polished along with the second pre-outer molding layer 11BP of FIG. 14, and the upper ends of the bonding wires 51, 52, and 53, the upper ends of the metal pillars 23D, 23E, and 23F, and the top surface of the second inner molding layer 12B are exposed at the top surface of the second outer molding layer 11B. The upper ends of the bonding wires 51, 52, and 53, the top surface of the second inner molding layer 12B, and the upper ends of the metal pillars 23D, 23E, and 23F are disposed in substantially the same plane as the top surface of the second outer molding layer 11B in an embodiment.

Referring to FIG. 1, a redistribution layer 60 and an external connection terminal 70 are formed.

The redistribution layer 60 is disposed on the upper ends of the bonding wires 51, 52, and 53, the upper ends of the metal pillars 23D, 23E, and 23F, the top surface of the second inner molding layer 12B, and the top surface of the second outer molding layer 11B.

The redistribution layer 60 includes the redistribution pads 61A to 61F, redistribution patterns 64 and a dielectric layer 63 that insulates the redistribution pads 61A to 61F and the redistribution patterns 64. The redistribution pads 61A, 61B, and 61C are disposed on the bonding wires 51, 52, and 53, respectively. The redistribution pads 61D, 61E, and 61F are disposed on the metal pillars 23D, 23E, and 23F, respectively.

The redistribution patterns 64 are connected to at least one of the redistribution pads 61A to 61F. Some of the redistribution patterns 64 include ball lands 64A. The ball lands 64A are disposed on the dielectric layer 63. External connection terminals 70 are attached to the ball lands 64A. The external connection terminals 70 include solder balls.

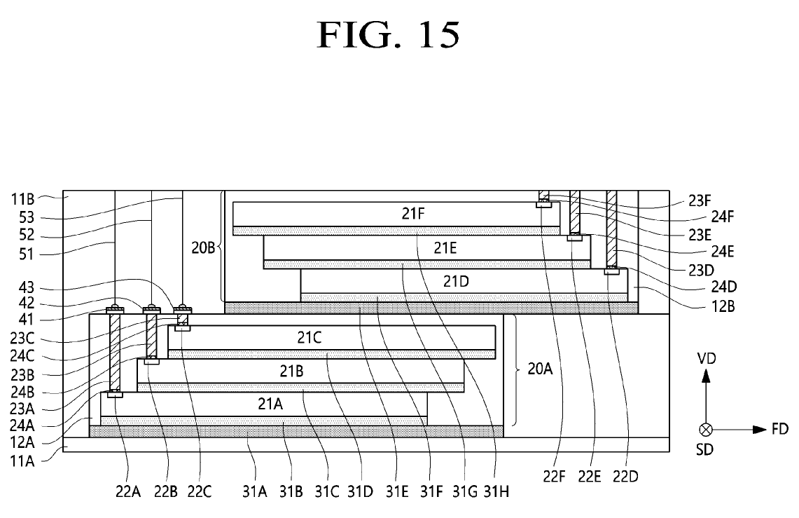

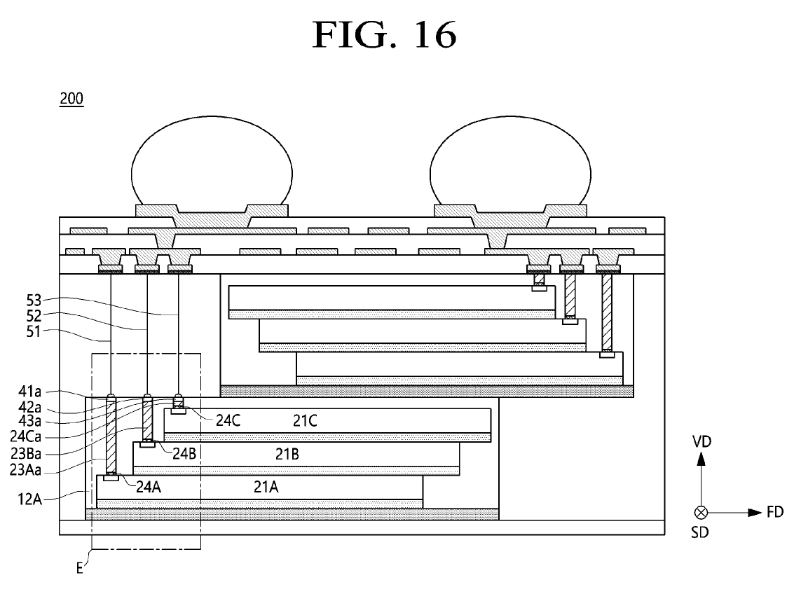

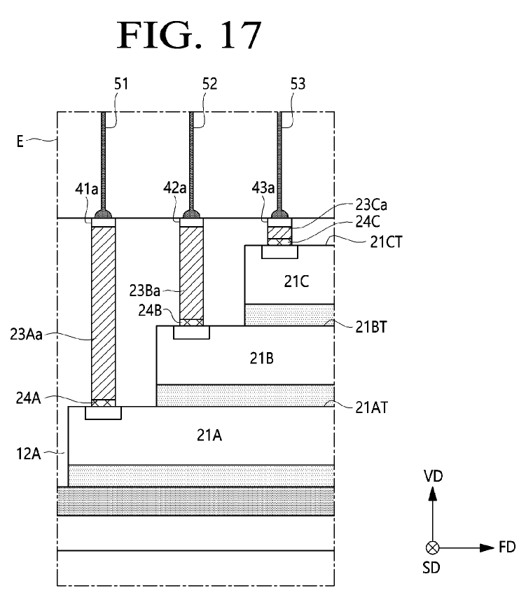

FIG. 16 is a cross-sectional view illustrating a semiconductor package according to an embodiment of the present disclosure. FIG. 17 is an enlarged view of a section E of FIG. 16. Components of FIG. 16 and FIG. 17 are described with reference to FIG. 1 - FIG. 15.

Referring to FIG. 16 and FIG. 17, a first bonding pad 41a is disposed on a first metal pillar 23Aa. The first bonding pad 41a covers the top surface of the first metal pillar 23Aa. The width of the first bonding pad 41a in the first direction FD may be the same as the width of the first metal pillar 23Aa in the first direction FD. The planar area of the upper surface of first metal pillar 23Aa may be the same as the planar area of the lower surface of the first bonding pad 41a. The top surface of the first metal pillar 23Aa is disposed closer to the top surface 21AT of the first semiconductor chip 21A than the top surface of the first inner molding layer 12A. Because the top surface of the first metal pillar 23Aa is positioned below the top surface of the first inner molding layer 12A, a distance between the top surface of the first metal pillar 23Aa and the top surface 21AT of the first semiconductor chip 21A is shorter than a distance between the top surface of the first inner molding layer 12A and the top surface 21AT of the first semiconductor chip 21A. The side surface of the first metal pillar 23Aa is surrounded by the first inner molding layer 12A. The top surface of the first bonding pad 41a is disposed in the same plane as the top surface of the first inner molding layer 12A. The side surface of the first bonding pad 41a is surrounded by the first inner molding layer 12A.

The first metal pillar 23Aa may include copper (Cu). The first metal pillar 23Aa may be a copper pillar. The first bonding pad 41a may include nickel. The first bonding pad 41a may include a nickel layer.

A process that forms the first metal pillar 23Aa may include forming a seed metal layer on the first semiconductor chip 21A, forming, on the seed metal layer, a plating resist pattern having an opening that provides a mold shape for the first metal pillar 23Aa, and plating copper into the opening of the plating resist pattern. The first bonding pad 41a may be formed by plating nickel into the opening of the plating resist pattern after forming the first metal pillar 23Aa. The plating resist pattern may be removed after forming the first bonding pad 41a. After the plating resist pattern is removed, the seed metal layer exposed by removal of the plating resist pattern may be removed. A second bonding pad 42a is disposed on a second metal pillar 23Ba. The second bonding pad 42a covers the top surface of the second metal pillar 23Ba. The width of the second bonding pad 42a in the first direction FD may be the same as the width of the second metal pillar 23Ba in the first direction FD. The planar area of the lower surface of the second bonding pad 42a may be the same as the planar area of the upper surface of the second metal pillar 23Ba. The top surface of the second metal pillar 23Ba is disposed closer to the top surface 21BT of the second semiconductor chip 21B than the top surface of the first inner molding layer 12A. The side surface of the second metal pillar 23Ba is surrounded by the first inner molding layer 12A. The top surface of the second bonding pad 42a may be disposed in the same plane as the top surface of the first inner molding layer 12A. The side surface of the second bonding pad 42a is surrounded by the first inner molding layer 12A. The second metal pillar 23Ba may include the same material as the first metal pillar 23Aa. The second bonding pad 42a may include the same material as the first bonding pad 41a.

A third bonding pad 43a is disposed on a third metal pillar 23Ca. The third bonding pad 43a covers the top surface of the third metal pillar 23Ca. The width of the third bonding pad 43a in the first direction FD may be the same as the width of the third metal pillar 23Ca in the first direction FD. The planar area of the lower surface of the third bonding pad 43a may be the same as the planar area of the upper surface of the third metal pillar 23Ca. The top surface of the third metal pillar 23Ca is disposed closer to the top surface 21CT of the third semiconductor chip 21C than the top surface of the first inner molding layer 12A. The side surface of the third metal pillar 23Ca is surrounded by the first inner molding layer 12A. The top surface of the third bonding pad 43a may be disposed in the same plane as the top surface of the first inner molding layer 12A. The side surface of the third bonding pad 43a is surrounded by the first inner molding layer 12A. The third metal pillar 23Ca may be formed of the same material as the first metal pillar 23Aa . A semiconductor package may be formed by stacking semiconductor chips, forming bonding wires that extend vertically, on chip pads of the semiconductor chips, forming a molding layer that seals the semiconductor chips and the bonding wires, and forming, on the molding layer, a redistribution layer that is connected to the bonding wires.

To increase memory capacity, the number of stacked semiconductor chips is increased. Because the maximum formation height of a bonding wire is limited, the number of semiconductor chips that may be stacked is limited.

To connect a bonding wire to a chip pad of a lower semiconductor chip, an upper semiconductor chip is offset-stacked with respect to the lower semiconductor chip, and the upper semiconductor chip has an overhang that is not supported by the lower semiconductor chip. As the number of stacked semiconductor chips increases, the length of an overhang increases, and defects such as chip cracks and chip bending occur during the manufacturing process of the semiconductor package.

According to an embodiment of the present disclosure, semiconductor chips are formed as a chip structure or module, and chip structures or modules are stacked to form a semiconductor package, such that defects such as chip cracks and chip bending may be prevented or reduced. Because additional support, such as a dummy chip that supports the overhang of a semiconductor chip is not needed, an advantage may be provided in that forming the additional support need not be performed.

According to an embodiment of the present disclosure, because an upper chip module is directly connected to a redistribution layer and a lower chip module is connected to the redistribution layer through bonding wires, compared to the configurations in which all stacked chips are connected to the redistribution layer using bonding wires, the amount of bonding wire consumed may be reduced and the lengths of the bonding wires may be shortened. Wire sweeping may be suppressed as the lengths of the bonding wires are shortened.

In the configurations in which metal pillars are disposed on some of semiconductor chips and bonding wires are disposed on the other semiconductor chips, a process is divided and the number of processes to be controlled increases. According to an embodiment of the present disclosure, because metal pillars are disposed on each semiconductor chip, process unification is possible and the number of processes to be controlled decreases. Therefore, the time and effort consumed for process control may be reduced.

Although the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor package comprising:
a first outer molding layer;
a first chip structure disposed on the first outer molding layer and including a first semiconductor chip, a first metal pillar disposed on the first semiconductor chip, a second semiconductor chip offset-stacked on the first semiconductor chip, a second metal pillar disposed on the second semiconductor chip, and a first inner molding layer covering the first semiconductor chip and the second semiconductor chip and surrounding the first metal pillar and the second metal pillar;
a second chip structure disposed on the first chip structure and including a third semiconductor chip, a third metal pillar disposed on the third semiconductor chip, a fourth semiconductor chip offset-stacked on the third semiconductor chip, a fourth metal pillar disposed on the fourth semiconductor chip, and a second inner molding layer covering the third semiconductor chip and the fourth semiconductor chip and surrounding the third metal pillar and the fourth metal pillar;
a first bonding pad disposed on the first metal pillar;
a second bonding pad disposed on the second metal pillar;
a first bonding wire disposed on the first bonding pad;
a second bonding wire disposed on the second bonding pad;
a second outer molding layer covering the first chip structure and the first bonding pad and second bonding pad, and surrounding the second chip structure and the first bonding wire and the second bonding wire; and
a redistribution layer disposed on the second chip structure, the first bonding wire, the second bonding wire, and the second outer molding layer.

2. The semiconductor package according to claim 1, wherein
the first bonding pad is disposed on the first metal pillar and the first inner molding layer disposed around the first metal pillar, and
the second bonding pad is disposed on the second metal pillar and the first inner molding layer disposed around the second metal pillar.

3. The semiconductor package according to claim 2, wherein the first bonding pad and the second bonding pad each comprises:
a barrier metal layer; and
a bonding metal layer on the barrier metal layer.

4. The semiconductor package according to claim 3, wherein the barrier metal layer includes nickel.

5. The semiconductor package according to claim 3, wherein the bonding metal layer includes gold.

6. The semiconductor package according to claim 2, wherein
the planar area of a first surface of the first bonding pad is larger than the planar area of a second surface of the first metal pillar, and
the planar area of a third surface of the second bonding pad is larger than the planar area of a fourth surface of the second metal pillar.

7. The semiconductor package according to claim 2, wherein a first surface of the first metal pillar and a first surface of the second metal pillar are disposed in the same plane as a first surface of the first inner molding layer.

8. The semiconductor package according to claim 1, wherein a side surface of the first bonding pad and a side surface of the second bonding pad are surrounded by the second outer molding layer.

9. The semiconductor package according to claim 8, wherein
the planar area of a first surface of the first bonding pad is the same as the planar area of a second surface of the first metal pillar, and
the planar area of a third surface of the second bonding pad is the same as the planar area of a fourth surface of the second metal pillar.

10. The semiconductor package according to claim 8, wherein a first surface of the first bonding pad and a first surface of the second bonding pad are disposed in the same plane as a first surface of the first inner molding layer.

11. The semiconductor package according to claim 8, wherein the first bonding pad and the second bonding pad include nickel.

12. The semiconductor package according to claim 1, wherein
the first metal pillar is disposed on a chip pad of the first semiconductor chip,
the second metal pillar is disposed on a chip pad of the second semiconductor chip,
the planar area of a first surface of the first metal pillar is smaller than the planar area of a second surface of the chip pad of the first semiconductor chip, and
the planar area of a third surface of the second metal pillar is smaller than the planar area of a fourth surface of the chip pad of the second semiconductor chip.

13. The semiconductor package according to claim 1, wherein a gap between the first bonding pad and the second bonding pad is larger than a gap between the first metal pillar and the second semiconductor chip.

14. The semiconductor package according to claim 1, wherein the redistribution layer comprises:
a first redistribution pad disposed on the first bonding wire;
a second redistribution pad disposed on the second bonding wire;
a third redistribution pad disposed on the third metal pillar;
a fourth redistribution pad disposed on the fourth metal pillar;
a redistribution pattern connected to at least one of the first redistribution pad, the second redistribution pad, the third redistribution pad, and the fourth redistribution pad; and
a redistribution insulating layer covering the first redistribution pad, the second redistribution pad, the third redistribution pad, the fourth redistribution pad, and the redistribution pattern.

15. The semiconductor package according to claim 14, further comprising:
a first pad base metal layer between the first redistribution pad and the first bonding wire;
a second pad base metal layer between the second redistribution pad and the second bonding wire;
a third pad base metal layer between the third redistribution pad and the third metal pillar; and
a fourth pad base metal layer between the fourth redistribution pad and the fourth metal pillar.

16. The semiconductor package according to claim 15, wherein the first base metal layer, the second base metal layer, the third base metal layer, and the fourth pad base metal layer include titanium or titanium nitride.

17. The semiconductor package according to claim 14, wherein
the planar area of a first surface of the first redistribution pad is larger than the planar area of a second surface of the first bonding wire,
the planar area of a third surface of the second redistribution pad is larger than a fourth surface of the planar area of the second bonding wire,
the planar area of a fifth surface of the third redistribution pad is larger than a sixth surface of the planar area of the third metal pillar, and
the planar area of a seventh surface of the fourth redistribution pad is larger than the planar area of an eighth surface of the fourth metal pillar.

18. The semiconductor package according to claim 1, wherein
the first bonding wire includes a first bonding section coupled to the first bonding pad,
the second bonding wire includes a second bonding section coupled to the second bonding pad,
the planar area of a first surface of the first bonding pad is larger than the planar area of a second surface of the first bonding section, and
the planar area of a third surface of the second bonding pad is larger than the planar area of a fourth surface of the second bonding section.

19. The semiconductor package according to claim 1, wherein a first surface of the second inner molding layer and a first surface of the second outer molding layer are disposed in the same plane.

20. A semiconductor package comprising:
a first outer molding layer;
a first semiconductor chip disposed on the first outer molding layer;
a first metal pillar disposed on the first semiconductor chip;
a second semiconductor chip offset-stacked on the first semiconductor chip;
a second metal pillar disposed on the second semiconductor chip;
a first inner molding layer covering the first semiconductor chip and the second semiconductor chip and surrounding the first metal pillar and the second metal pillar;
a third semiconductor chip disposed on the first inner molding layer;
a third metal pillar disposed on the third semiconductor chip;
a fourth semiconductor chip offset-stacked on the third semiconductor chip;
a fourth metal pillar disposed on the fourth semiconductor chip;
a second inner molding layer covering the third semiconductor chip and the fourth semiconductor chip and surrounding the third metal pillar and fourth metal pillar;
a first bonding pad disposed on the first metal pillar;
a second bonding pad disposed on the second metal pillar;
a first bonding wire disposed on the first bonding pad;
a second bonding wire disposed on the second bonding pad;
a second outer molding layer covering the first inner molding layer, the first bonding pad, and the second bonding pad and surrounding the second inner molding layer, the first bonding wire, and the second bonding wire; and
a redistribution layer disposed on the first bonding wire, the second bonding wire, the third metal pillar, the fourth metal pillar, the second inner molding layer, and the second outer molding layer.
